(19) United States
(12) Patent Application Publication
(10) Pub. No.: US 2025/0372385 A1
(43) Pub. Date: Dec. 4, 2025

(54) METHODS FOR GAP FILLING VERTICAL AND LATERAL FEATURES WITH PLASMA INHIBITION

(71) Applicant: Applied Materials, Inc., Santa Clara, CA (US)

(72) Inventors: Bhaskar SOMAN, Santa Clara, CA (US); Supriya GHOSH, San Jose, CA (US); Yanze WU, Santa Clara, CA (US); Sukrant DHAWAN, Santa Clara, CA (US); Susmit SINGHA ROY, Mountain View, CA (US); Akhil SINGHAL, Santa Clara, CA (US); Abhijit Basu MALLICK, Fremont, CA (US)

(21) Appl. No.: 18/677,177

(22) Filed: May 29, 2024

(51) Int. Cl. H01L 21/285; H01J 37/32; H01L 21/02

(52) U.S. Cl. CPC H01L 21/28562; H01J 37/32082; H01J 37/32449; H01L 21/02164

(57) ABSTRACT

A method of processing a substrate with a vertical feature and a plurality of lateral features extending from the vertical feature is provided. The method includes exposing surfaces of the vertical feature and the plurality of lateral features to an anisotropic plasma generated from an inhibiting gas mixture to form an inhibition gradient on surfaces of the vertical feature and the plurality of lateral features, and depositing a gapfill structure in the vertical feature and lateral features. In an embodiment, the inhibition gradient provides for varying the growth rate of the gapfill structure in the vertical feature and the plurality of lateral features.

### BACKGROUND

### Field

Embodiments of the present disclosure generally relate to manufacture of semiconductor components and devices. More specifically, embodiments described herein provide methods for forming gapfill structures in substrates having vertical and lateral features.

### Description of the Related Art

The integrated circuit (IC) market is continually demanding greater memory capacity, faster switch speeds, and greater feature density. A trend in the evolution of semiconductor technology based upon integrated circuits is an increase in device density within a semiconductor die, and an increase in device functionality. In the case of memory devices, such as dynamic random access memory (DRAM), one factor that improves memory size for a DRAM chip for a given die area is the shrinking of the cell size for individual memory cells. One approach that is envisioned to increasing memory size within a given die area is to fabricate three dimensional memory, such as three dimensional (3D) DRAM. In this case, multiple memory cells may be stacked in layers, one upon another in a “vertical” direction, orthogonal to the main plane of the semiconductor die. However, such 3D devices can result in a new set of challenges for processing and fabrication.

For example, in manufacturing of semiconductor devices, gapfill processes are used to fill high aspect ratio gaps (or features) with an insulating or conducting material. For example, shallow trench isolation, inter-metal dielectric layers, passivation layers, dummy gate, etc. As device geometries shrink and thermal budgets are reduced, defect-free filling of gaps and other features becomes increasingly difficult due to limitations of conventional deposition processes. Conventional deposition processes for forming gapfill structures have focused on forming seam free and void free gapfill structures in vertical high aspect ratio trenches. However, in fabricating 3D DRAM memory stacks for example, such vertical trenches may include additional lateral trenches that may also need to be filled with seam free and void free gapfill structures.

Accordingly, a need exists for improvement in methods for forming gapfill structures in substrates having vertical and lateral features formed therein.

### SUMMARY

In an embodiment, a method of processing a substrate is provided. The method includes flowing an inhibiting gas mixture into a processing volume of a process chamber, the processing volume having a substrate with a feature formed therein. The feature includes a vertical feature and a plurality of lateral features extending from the vertical feature. The vertical feature is formed in a top surface of the substrate and is in fluid communication with the plurality of lateral features extending beneath the top surface of the substrate. A longitudinal axis of each the plurality of lateral features extends substantially parallel with the top surface of the substrate. The method also includes exposing surfaces of the vertical feature and the plurality of lateral features to an anisotropic plasma generated from the inhibiting gas mixture to form an inhibition gradient on surfaces of the vertical feature and the plurality of lateral features, and depositing a gapfill structure in the vertical feature and lateral features. When depositing the gapfill structure, the inhibition gradient causes the growth rate of the gapfill structure on surfaces near an opening of the vertical feature to be less than the growth rate of the gapfill structure on surfaces near a bottom surface of the vertical feature, and the growth rate of the gapfill structure on surfaces near openings of the lateral features to be less than growth rate of the gapfill structure on surfaces end surfaces of the lateral features.

In another embodiment, a method of processing a substrate is provided. The method includes flowing an inhibiting gas mixture into a processing volume of a process chamber, the processing volume having a substrate with a feature formed therein and the feature comprising a vertical feature formed in a top surface of the substrate and in fluid communication with a plurality of lateral features extending from the vertical feature. The plurality of lateral features are formed in which a longitudinal axis of each the plurality of lateral features is substantially perpendicular with a longitudinal axis of the vertical feature. The method also includes exposing surfaces of the vertical feature and the plurality of lateral features to an anisotropic plasma generated from the inhibiting gas mixture to form an inhibition gradient on surfaces of the vertical feature and the plurality of lateral features, exposing surfaces of the vertical feature and the plurality of lateral features to a precursor gas to chemisorb a layer of precursors on uninhibited surfaces of the vertical feature and the plurality of lateral feature, exposing the layer of precursors to a reactant plasma of a reactant gas to deposit a gapfill material layer on the vertical feature and the plurality of lateral features, and cyclically repeating the exposure to the precursor gas and the deposition of the gapfill material layer to form a gapfill structure and fill the vertical feature and the plurality of lateral feature.

In one embodiment, a method of processing a substrate is provided. The method includes positioning a substrate into a processing volume of a process chamber, the substrate having a feature formed therein. The feature includes a vertical feature and a plurality of lateral features extending from the vertical feature, the vertical formed in a top surface of the substrate and in fluid communication with the plurality of lateral features. The plurality of lateral features extends substantially parallel with and beneath the top surface of the substrate. The method also includes performing a plasma nitridation process to treat the substrate. The plasma nitridation process preferentially forms amine groups on active sites of surfaces near an opening of the vertical feature and openings of the lateral features as compared to surfaces near a bottom surface of the vertical feature and surfaces near end surfaces of the lateral features, respectively. The method also includes exposing surfaces of the vertical feature and the plurality of lateral features to a precursor gas comprising precursors to chemisorb precursors on available active sites remaining on surfaces of vertical feature and the plurality of lateral features, exposing the precursors on the vertical feature and the plurality of lateral features to a reactant to deposit a gapfill material layer in the vertical feature and lateral features, and cyclically repeating exposure to the precursor gas and the gapfill material layer deposition to fill the vertical feature and the plurality of lateral feature.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a flow diagram of a method for forming a gapfill structure in a feature of a substrate, according to certain embodiments, and

FIGS. 2A-2F show schematic side views of a gapfill structure being formed by the method of FIG. 1, according to certain embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to apparatus and methods for the deposition of thin films to form gapfill structures in a substrate. Certain details are set forth in the following description and figures to provide a thorough understanding of various implementations of the disclosure. Other details describing well-known methods and systems often associated with the deposition of thin films are not set forth in the following disclosure to avoid unnecessarily obscuring the description of the various implementations.

Many of the details, components and other features described herein are merely illustrative of particular implementations. Accordingly, other implementations can have other details, components, and features without departing from the spirit or scope of the present disclosure. In addition, further implementations of the disclosure can be practiced without several of the details described below.

A “substrate” as used herein refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates may be exposed to a pretreatment process to polish, etch, reduce, oxidize, hydroxylate, anneal and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

Embodiments of the present disclosure provide for formation of seam free and void free gapfill structures in vertical features (e.g., vertical trenches) formed in substrates in which the vertical trench further includes a plurality of lateral features (e.g., lateral trenches, inter tier dielectric fill) extending from the sidewalls of the vertical feature. In some embodiments, the lateral features include openings formed in the vertical sidewalls of the vertical feature and extend horizontally away from the sidewalls of the vertical feature such that the lateral features are in fluid communication with the vertical feature. More specifically, embodiments of the present disclosure are directed to methods of partially inhibiting certain surfaces of both the vertical trenches and lateral trenches connected thereto and subsequently forming a gapfill structure that completely fills each of the lateral trenches and the vertical trench.

As used herein, the term “feature” means any intentional surface irregularity. The shape of the feature can be any suitable shape including, but not limited to, trenches and cylindrical vias. Suitable examples of features include, but are not limited to trenches which have an opening, two sidewalls and a bottom, and vias which have a generally cylindrical sidewall. Other examples of features include without limitation, lines, contact holes, through-holes or other feature definitions utilized in a semiconductor, solar, or other electronic devices, such as high aspect ratio contact plugs.

In an embodiment, the method uses an atomic layered deposition (ALD) process to form the gapfill structure. ALD has evolved significantly in the recent years and can be regarded as a special type of chemical vapor deposition (CVD) process. Generally, ALD is a technique for growing thin films in which the substrate surface is exposed to precursors (or reactive gases) sequentially or substantially sequentially to form the desired film via chemical surface reactions. As used herein throughout the present disclosure, “substantially sequentially” means that a majority of the duration of a precursor exposure does not overlap with the exposure to a co-reagent, although there may be some overlap. As used in this specification and the appended claims, the terms “precursor”, “reactant”, “reactive gas” and the like are used interchangeably to refer to any gaseous species that can react with the substrate surface.

In one or more embodiment, the method of the present disclosure is performed using cycles of ALD to form the gapfill structure one layer at a time. ALD is a self-limiting process where a single monolayer of the gapfill material is deposited using a binary (or higher order) reaction. The technique relies on alternating half-cycle reactions of typically a gas-phase precursor and a gas-phase reactant with each reaction separated by pump and/or inert gas purge steps. An individual reaction in the ALD process continues until the precursor/reactant is chemisorbed all available active sites on the substrate surface resulting in the formation of a monolayer of the film. Ideally, the successive, self-terminated surface reactions after each cycle provide controlled growth of the desired thin film material one monolayer at a time.

One of the features of ALD as a process is that the film deposited is conformal with the substrate surface, even in complicated 3D features. However, as the aspect ratio of features (e.g., the vertical feature and lateral features extending therefrom) increase, conventional techniques for gap filling such features using ALD can lead to void formation inside the lateral trenches due to the premature pinching off at the opening of the lateral trenches, or within the vertical trench itself as the gapfill material deposited on the sidewalls of the vertical trench pinch off prematurely leaving seams or voids between portions of the gapfill structures formed in opposing lateral trenches.

To assist in forming gapfill structures that completely fill both the vertical feature and the lateral features extending therefrom, the methods of the present disclosure utilize an anisotropic inhibition process to treat certain surfaces of the vertical and lateral features prior to depositing the gapfill material. In an embodiment, the anisotropic inhibition process may partially inhibit the chemisorption of ALD precursors on certain surfaces of the vertical and lateral features. Without being bound by theory, it is believed the anisotropic inhibition process reduces the chemisorption of the precursor of the gapfill structure such that the growth rate of the gapfill structure is reduced on such partially inhibited surfaces. For example, in some embodiment, the anisotropic inhibition process may preferentially partially inhibit selected regions of surfaces of the vertical feature and lateral features near the respective openings of the features as compared to surfaces of the features farther from each of the respective openings. The partial inhibition of the various surfaces of the features in turn may provide for the gapfill structure being deposited to grow faster on non-inhibited or less inhibited surfaces of the vertical and lateral features that are generally more difficult for the precursor/reactants for forming the gapfill structure to reach. Accordingly, the present disclosure provides for tuning the deposition profile of the gapfill structure in both the vertical and lateral features to in turn minimize or eliminate the formation of seams and voids.

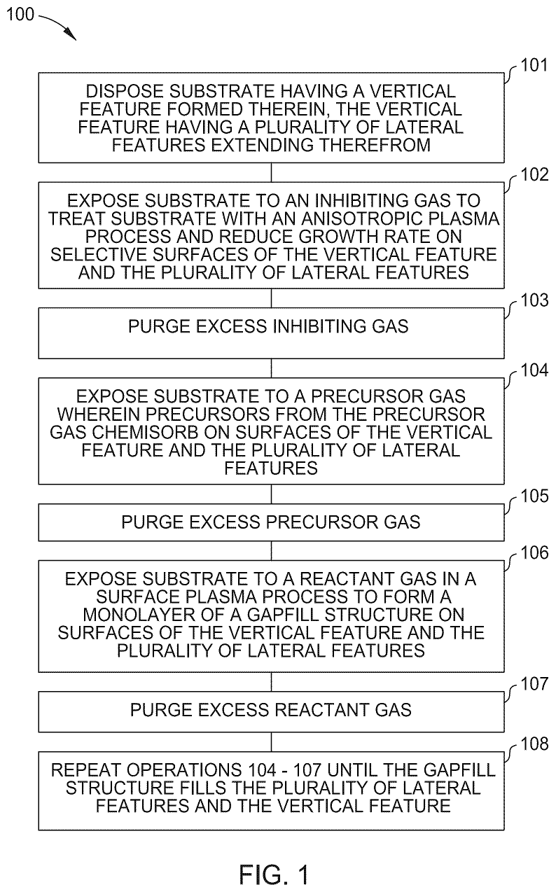

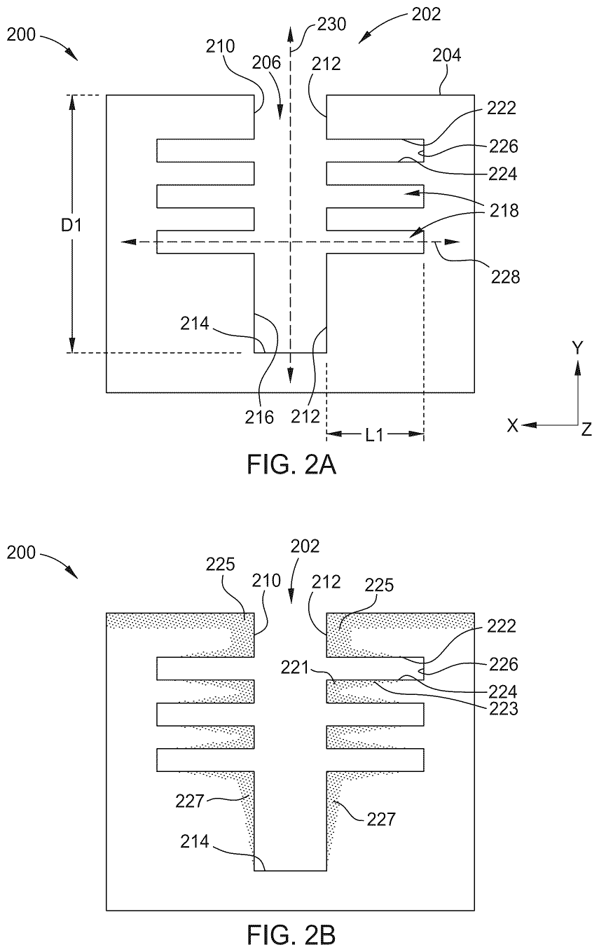

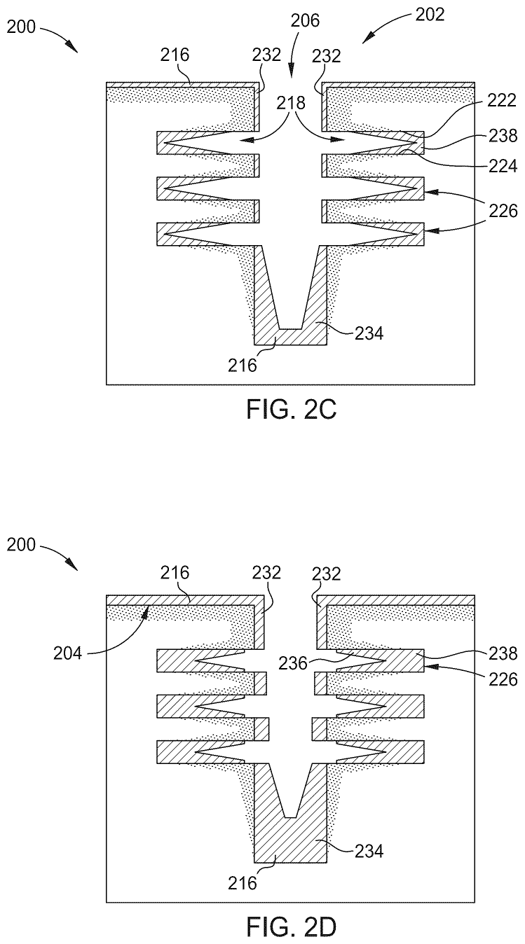

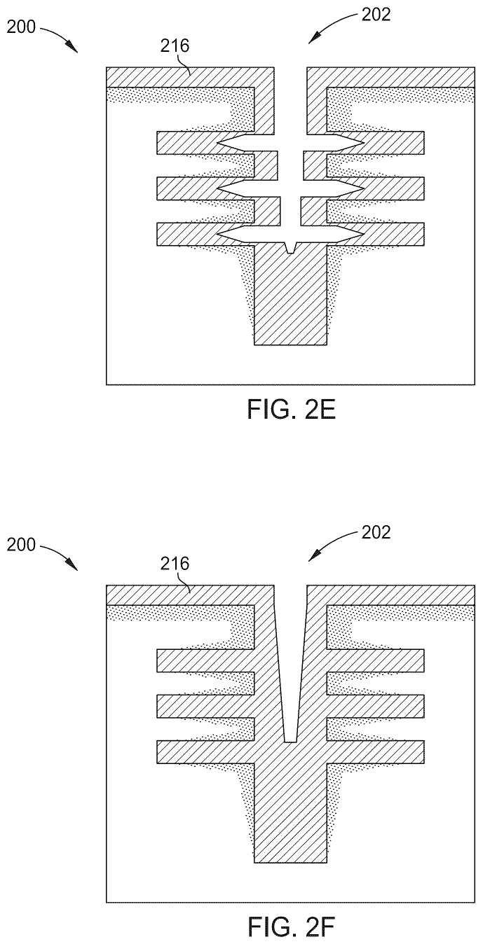

FIG. 1 depicts a flow diagram of a method 100 for forming a gapfill structure, according to certain embodiments of the present disclosure. The processing method 100 described in FIG. 1 corresponds to the fabrication stages depicted in FIGS. 2A-2F, which are discussed below. FIGS. 2A-2F depict cross-sectional views of a substrate 200 with a feature 202 formed thereon during different stages of forming the gapfill structure within the feature 202, according to the method 100.

In an embodiment, method 100 begins in operation 101 in which the substrate 200 is positioned within a processing volume of a process chamber. As shown in FIG. 2A, a feature 202 is show formed in the substrate 200. The feature 202 includes a vertical trench 206 having an opening in a top surface 204 of the substrate 200. The opening is created between a first sidewall 210 and a second sidewall 212 opposite a bottom surface 214. The vertical trench 206 extends a vertical depth D1 from the opening to the bottom surface 214. In certain embodiments, the vertical depth D1 of the vertical trench 206 may be between about 4 microns and about 8 microns. In certain embodiments, the vertical trench 206 may be formed with a critical dimension between about 45 nm and about 100 nm. In certain embodiments, the vertical trench 206 may be formed with an aspect ratio between about 80:1 and about 120:1.

In an embodiment, the substrate 200 includes materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. In an embodiment, the substrate 200 may comprise a plurality of material layers arranged in a vertical stack. For example, the substrate 200 may comprise a plurality of alternating layers of a horizontal insulating layer, such as oxide or silicon oxide layers. In other embodiments, the substrate 200 may also include layers of a placeholder or sacrificial material, which may be silicon nitride or polysilicon. In other embodiments, the substrate may include a plurality of material layers formed overlying the substrate 200 with the feature 202 formed in the plurality of material layers on the substrate 200

In an embodiment, the feature 202 also includes a plurality of lateral trenches 218 with openings in the first and second sidewalls 210, 212 of the vertical trench 206. Each of the openings of the plurality of lateral trenches 218 is created between a third sidewall 222 and a fourth sidewall 224 opposite an end surface 226. Each of the lateral trenches 218 is in fluid communication with the vertical trench 206. In certain embodiments, each of the lateral trenches 218 extending from the first sidewall 210 of the vertical trench 206 includes a corresponding and opposite lateral trench 218 extending from the second sidewall 212. In some embodiments, the lateral trenches 218 in the first sidewall 210 may be aligned with the lateral trenches 218 in the second sidewall 212. In some embodiments, the lateral trenches 218 in the first and second sidewalls 210, 212 may not be aligned and may instead be staggered. As shown, the lateral trenches 218 may each extend in the X direction along a longitudinal axis 228 extending substantially parallel with and beneath the top surface 204 of the substrate 200. The longitudinal axis 228 may also extend substantially perpendicular with a longitudinal axis 230 of the vertical trench 206 extending in the Y direction.

In an embodiment, the lateral trenches 218 extend a length L1 between the opening and the end surface 226. In certain embodiments, the length L1 of the lateral trenches 218 may be between about 0.3 microns and about 1.5 microns, such as between about 0.5 microns and about 1.25 microns. In some embodiments, each of the lateral trenches 218 may comprise about the same length L1. In some embodiments, the lateral trenches 218 may be formed with varying lengths L1

In certain embodiments, each of the lateral trenches 218 may be formed with a critical dimension between about 10 nm and about 25 nm. In some embodiments, the plurality of lateral trenches 218 may all be formed with the same critical dimension. In some embodiments, the plurality of lateral trenches 218 may be formed with varying critical dimensions. In certain embodiments, each of the lateral trenches 218 may be formed with an aspect ratio between about 30:1 and about 50:1. In some embodiments, the plurality of lateral trenches 218 may all be formed with the same aspect ratio. In some embodiments, the plurality of lateral trenches 218 may be formed with varying aspect ratio.

In operation 102, an anisotropic (directional) plasma inhibition process is performed to treat surfaces of the feature 202 with a growth inhibitor configured to adsorb to surfaces of the feature 202 and effectively inhibit selected regions of surfaces of feature 202. In an embodiment, the growth inhibitor may comprise radicals or other activated species from a generated plasma that partially inhibit chemisorption of precursors on surfaces of the feature 202 necessary for film growth during deposition of the gapfill structure. In an embodiment, operation 102 includes flowing an inhibiting gas into the processing volume of the process chamber with the substrate, generating an inhibiting plasma from the inhibiting gas, and exposing surfaces of the substrate 200 and the feature 202 formed therein to radicals or other activated species of the inhibiting plasma.

In an embodiment, the inhibiting plasma generated from the inhibiting gas may produce radicals or ions that can be directed towards surfaces of the feature 202 (e.g. the first and second sidewalls 210, 212 of the vertical trench 206, and surfaces of the third and fourth sidewalls 222, 224 of the lateral trenches 218). In an embodiment, exposure of surfaces of the feature 202 to the radicals or activated species of the inhibiting plasma inhibits or generally passivates the treated surfaces of the feature 202. Passivation by the activated species includes the radicals or activated species adsorbing with active sites or molecules on the feature surface to effectively inhibit further reaction with such molecules of the substrate and reduce the number of active sites available on the feature surface for chemisorption by precursors for forming he gapfill structure.

In an embodiment, the activated species or ions of the directional plasma may preferentially react with surface regions near openings of the vertical trench 206 and the lateral trenches 218 to inhibit such regions with a greater intensity. In surface regions inhibited with increased intensity, the number of available active sites necessary for precursor chemisorption or film growth are further reduced as compared to number of active sites on uninhibited surfaces or regions of surfaces inhibited with a lower intensity. Further reducing the number active sites available for chemisorption of precursors translates to further reducing film growth rate on such regions when forming the gapfill structure.

As shown in FIG. 2B, in an embodiment, the plasma inhibition process may preferentially inhibit surfaces of the first and second sidewalls 210, 212 near the opening of the vertical trench 206 as compared to surfaces near the bottom surface 214 and thereby. The preference to inhibit or inactivate a greater number of active sites in such surfaces forms an inhibition gradient that decreases in intensity through the feature 202. In an embodiment, the inhibition gradient formed in the vertical trench 206 includes the greatest intensity of inhibition at an upper portion and decreases towards a lower portion of the vertical trench 206 (e.g., towards the bottom surface 214). In an embodiment, the inhibition process may preferentially also inhibit surfaces of the third and fourth sidewalls 222, 224 near the opening of the lateral trenches 218 so as to form an inhibition gradient through each of the lateral trenches 218. In an embodiment, the inhibition gradient formed in the lateral trenches 218 include the greatest intensity of inhibition at an upper portion 221 and decreases towards a posterior portion 223 in each of the lateral trenches 218 (e.g., towards the end surface 226).

In an embodiment, the anisotropic inhibiting plasma of operation 102 may be generated by applying a RF power to the inhibiting gas being flown into the processing volume of the process chamber. In an embodiment, the RF power applied may be controlled at between about 125 W and about 2250 W. In an embodiment, the RF power may be a dual RF power that includes applying a high frequency RF power between about 100 W and about 200 W, and a low frequency RF power between about 25 W and about 25 W. In an embodiment, operation 102 may include exposing the substrate 200 and the feature 202 to the generated plasma for an exposure time between about 1 sec. and about 10 sec., such as for about 5 sec.

In an embodiment, operation 102 may be performed at a processing temperature between about 400° C. and about 550° C. in which a chamber pressure is controlled to be between about 1 Torr and about 50 Torr. In an embodiment, the inhibiting gas may be flowed to the processing volume at a flow rate between about 100 sccm and about 5000 sccm, such as about 4000 sccm.

In other embodiments, the chemistry of the growth inhibitor and the processing parameters for the plasma inhibition process in operation 102 may depend the material of the substrate 200, the dimensions of the feature 202 (e.g., the critical dimensions and aspect ratios of the vertical trench 206 and lateral trenches 218) in the substrate 200, and/or the material of the gapfill structure to be deposited in the feature 202. For example, in an embodiment, the processing parameters for the plasma inhibiting process, such as the substrate temperature, processing pressure, and dual RF power applied may be tuned to determine the amount and/or the lifetime of the inhibiting radical or activated species generated. Tuning the processing parameters for operation 102 provides for ensuring effective partial inhibition on selected surfaces of both the vertical trench 206 and lateral trenches 218 in operation 102. For example, the plasma inhibition process may be tuned to modulate the extent of inhibition of surfaces of the vertical trench 206 to minimize inhibition near the bottom surface 214, and/or vary the intensity of inhibition on selected regions of the first and second sidewalls 210, 212, such as regions near the opening of the trench 206. In an embodiment, which may be combined with other embodiments described herein, the processing parameters may also be tuned to control the extent or intensity of inhibition on surfaces of the lateral trenches 218, such as regions of the third and fourth sidewalls 222, 225 of each of the lateral trenches 218. For example, the processing parameters may be tuned to ensure a sufficient amount of radicals or other inhibiting species are generated to reach and effectively inhibit surfaces of the lateral trenches 218. The processing parameters may also be tuned to inhibit surface region near the openings of the lateral trenches 218 with greater intensity, as compared to surface regions near each of end surfaces 226 of the lateral trenches 218.

In an embodiment, the anisotropic plasma inhibition process may include performing a plasma nitridation process. In such an embodiment, the inhibiting gas may include a nitrogen containing gas such as N₂, NH₃, hydrazine (N₂H₄), N₂+H₂, or combinations thereof. In other embodiments, the inhibiting gas may alternatively contain CO₂ or a hydrocarbon compound having a general formula CₓH_{y} where x has a range of between 1 and 20, and y has a range of between 1 and 20.

As discussed above, in some embodiments, the chemistry of the gapfill structure to be formed may also determine the chemistry and processing parameters of the plasma inhibition process used in operation 102. For example, in the case where the gapfill structure to be formed to fill the features 202 includes performing an ALD process to form SiO₂ using bis(diethylamino)silane (BDEAS) and O₂ plasma, operation 102 may include employing a NH₃ plasma nitridation process before exposing the surfaces of the feature 202 to BDEAS followed by an O2 plasma oxidation process. The nitridation process in turn may reduce the growth rate of the SiO₂ film on selected regions of surfaces of the vertical trench 206 and lateral trenches 218. Without being bound to any particular theory of operation, it is believed that the mechanism by which the reduction of growth occurs is from the formation of surface NH₂ groups on surfaces of the features which are not able to react with the amine groups on the BDEAS thereby reducing the number of available active sites on the surfaces of the features that the precursor of the ALD process can chemisorb onto.

In operation 103, a purge process is performed to remove some or all of the reactants of the inhibiting gas provided for the plasma inhibition process in operation 102. In some embodiments, an inert gas is used as a purge gas to remove some or all of the reactants. In an embodiment, Ar or N₂ gas may be flowed as a purge gas in operation 103 at a flow rate between about 100 sccm and about 5000 sccm. In some embodiments, purging the excess reactants of the inhibiting gas may performed at a processing temperature between about 400° C. and about 550° C. in which the purge gas is flowed at a chamber pressure between about 1 Torr and about 50 Torr.

In operation 104, the first half of an ALD process cycle is performed by exposing the feature 202 to a precursor gas for forming the gapfill structure. When surfaces of the feature 202 are exposed to the precursor gas, surfaces of the feature 202 are dosed with the precursors in which the precursors chemisorb to surfaces of the feature 202. Due to the partial inhibition of the surfaces of the vertical trench 206 and the lateral trenches 218 in operation 102, the amount of precursors chemisorbed on less inhibited surfaces of the vertical trench 206 is greater which translates to increased growth rate as compared to more inhibited surfaces of the vertical trench 206. The varying film growth rate in the vertical trench 206 provides for forming the gapfill structure in the vertical trench 206 in a bottom up manner. With respect to the lateral trenches 218, the partial inhibition of selected surfaces similarly causes the amount of precursors chemisorbed on the third and fourth sidewalls 222, 224 to vary with a greater amount of precursors chemisorbed on less inhibited surfaces of the lateral trenches 218 and greater film growth rate. The varying film growth rate in the lateral trenches 218 provides for forming the gapfill structure in each of the lateral trenches 218 in an end in manner (e.g., from the end surface 226 towards the opening of the lateral trenches 218).

In an embodiment, the precursor gas is selected based on the desired material of the gapfill structure to be formed. In an embodiment in which the desired material of the gapfill structure is silicon oxide (SiO2), the precursor gas may be silane, such as bis(diethylamino)silane (BDEAS) gas. In an embodiment, operation 104 may be performed at a processing temperature between about 400° C. and about 550° C. in which the precursor gas is provided at a chamber pressure between about 1 Torr and about 50 Torr. In an embodiment, the feature 202 may be exposed to the precursor gas in operation 104 for a time between about 0.5 sec. and about 5 sec.

In operation 105, a purge process is performed to remove some or all of the precursors of the precursor gas provided in operation 104. In some embodiments, an inert gas is used as a purge gas to remove some or all of the precursors. In an embodiment, Ar or N₂ gas may be flowed as a purge gas in operation 105 at a flow rate between about 100 sccm and about 5000 sccm. In some embodiments, purging the excess precursors of the precursor gas may performed at a processing temperature between about 400° C. and about 550° C. in which the purge gas is flowed at a chamber pressure between about 1 Torr and about 50 Torr.

In operation 106, the second half of the ALD process cycle is performed by exposing the substrate 200 (and the precursors chemisorbed onto surfaces of the feature 202) to a reactant gas in a surface plasma process. When exposed to the reactant gas, the reactants generated react with the chemisorbed precursors on surfaces the feature 202 to form a film 216, as shown in FIG. 2C. In an embodiment, the reactant gas may be selected based on the precursor gas used and the desired material of the gapfill structure to be formed in the feature 202.

In an embodiment in which the desired material of the gapfill structure is silicon oxide (SiO₂) and the precursor gas provided in operation 104 for providing silicon precursors includes BDEAS gas, the reactant gas flowed may include oxygen containing gases such O₃, O₂, or H₂O for performing a plasma oxidation process. The plasma oxidation process in operation 106 causes the silicon precursor to oxidize and form a monolayer of silicon oxide (SiO₂). As the silicon oxide is formed from oxidation of the silicon precursors chemisorbed on the surfaces of the feature 202, the formation of the silicon oxide therefore follows the varying concentration of precursors chemisorbed on the feature surface in operation 104. As such, the concentration of silicon oxide is formed in operation 106 similarly varies across the surface of the vertical trench 206 and the lateral trenches 218.

In an embodiment, the plasma oxidation process of operation 106 may be performed at a processing temperature between about 400° C. and about 550° C. in which the substrate 200 and the feature 202 is maintained at a chamber pressure between about 1 Torr and about 50 Torr. In an embodiment, the RF power for generating the plasma may be controlled at between about 125 W and about 2250 W. In an embodiment, the RF power may include applying a high frequency RF power between about 100 W and about 200 W, and a low frequency RF power between about 25 W and about 25 W. In an embodiment, the oxygen containing reactant gas for generating the plasma, such as O₂ gas, may be supplied at between about 5 sccm and 200 sccm. In an embodiment, the plasma oxidation process in operation 106 may last between about 0.25 sec. and about 10 sec, which may be stopped by discontinuing the flow of the oxygen containing reactant gas.

In another embodiment, a plasma nitridation process may alternatively be performed in operation 106 by flowing a nitrogen-containing reactant gas so as to grow silicon nitride (SiN) in the features 202 to form the gapfill structure.

In operation 107, a purge process is performed to remove some or all of the reactants of the reactant gas provided in operation 104. In some embodiments, an inert gas is used as a purge gas to remove some or all of the reactants. In an embodiment, Ar or N₂ gas may be flowed as a purge gas in operation 105 at a flow rate between about 100 sccm and about 5000 sccm. In some embodiments, purging the excess reactants of the reactants gas may performed at a processing temperature between about 400° C. and about 550° C. in which the purge gas is flowed at a chamber pressure between about 1 Torr and about 50 Torr.

In operation 108, operations 104 to 107 may be repeated for additional cycles to increase the thickness of the film 216. The cycle may be repeated until the gapfill structures completely fills the feature 202. The number of cycles required to form the gapfill structure may vary depending on the size of the feature 202. As shown in FIGS. 2C-2F, in an embodiment, due to the inhibition process of operation 102, the thickness of the film 216 at the top 232 in the vertical trench 206 grows at a slower rate than the thickness of the film 216 at the bottom 234. Accordingly, the film 216 may be formed in a bottom up “V” manner such that gap filling the vertical trench 206 resembles the closing of a “zipper” moved from the bottom surface 214 to the opening of the vertical trench 206. In an embodiment, due to the inhibition process of operation 102, the thickness 236 of the film 216 near the opening of the lateral trenches 218 may grow at a slower rate than the thickness 238 of the film 216 near the end surface 226 of the lateral trenches 218. Accordingly, the film 216 deposited in each of the lateral trenches 218 may similarly also be formed in a “V” manner such that gap filling the lateral trenches 218 resemble the closing of a “zipper” moved from the end surface 226 to the opening of the lateral trenches 218.

In certain embodiments, the ALD process in operations 104 to 107 can be performed by time-domain or spatial ALD. In a time-domain process, the process chamber and substrate are exposed to a single reactive gas at any given time. In an exemplary time-domain process, the process chamber might be filled with a metal precursor for a time to allow the metal precursor to fully react with the available sites on the substrate. The process chamber can then be purged of the precursor before flowing a second reactive gas into the process chamber and allowing the second reactive gas to fully react with the active sites on the substrate. The time-domain process minimizes the mixing of reactive gases by ensuring that only one reactive gas is present in the process chamber at any given time. At the beginning of any reactive gas step, there is a delay in which the concentration of the reactive species must go from zero to the final predetermined pressure. Similarly, there is a delay in purging all of the reactive species from the process chamber.

In a spatial ALD process, the substrate is moved between different process regions within a single process chamber. The substrate may be exposed to a precursor in one process region in the process chamber and then subsequently exposed to a reactant in another process region. Each of the individual process regions is separated from adjacent process regions by a gas curtain. The gas curtain helps prevent mixing of the precursor and reactive gases to minimize any gas phase reactions.

One or more embodiments of the present disclosure is directed the methods of forming gapfill structures in features comprising a vertical feature and a plurality of lateral features in fluid communication with the vertical feature. In some embodiments, the lateral features extend from and are substantially perpendicular with the vertical feature. In some embodiments, the gapfill structure is formed by exposing the substrate and feature therein to an inhibition plasma process to partially inhibit surfaces of the vertical and lateral features. In some embodiments, a film is deposited and grown in the feature utilizing an ALD process. The inhibited surfaces of the vertical and lateral features vary the growth rate of the film in each of the vertical and lateral features so as to grow a void and seam free gapfill structure in the vertical and lateral features.

While the foregoing is directed to embodiments of the present disclosure, other and further embodiments of the disclosure may be devised without departing from the basic scope thereof, and the scope thereof is determined by the claims that follow.

What is claimed is:

1. A method of processing a substrate, comprising:
flowing an inhibiting gas mixture into a processing volume of a process chamber having a substrate with a feature formed therein, the feature comprising a vertical feature, and a plurality of lateral features extending from the vertical feature, wherein:
the vertical feature is formed in a top surface of the substrate;
the vertical feature is in fluid communication with the plurality of lateral features extending beneath the top surface of the substrate; and
a longitudinal axis of each the plurality of lateral features extends substantially parallel with the top surface of the substrate;
exposing surfaces of the vertical feature and the plurality of lateral features to an anisotropic plasma generated from the inhibiting gas mixture to form an inhibition gradient on surfaces of the vertical feature and the plurality of lateral features; and
depositing a gapfill structure in the vertical feature and lateral features, wherein the inhibition gradient causes growth rate of the gapfill structure on surfaces near an opening of the vertical feature to be less than growth rate of the gapfill structure on surfaces near a bottom surface of the vertical feature, and growth rate of the gapfill structure on surfaces near openings of the lateral features to be less than growth rate of the gapfill structure on surfaces near end surfaces of the lateral features.

2. The method of claim 1, wherein the vertical feature comprises a first sidewall and a second sidewall on opposite sides of the opening and the bottom surface of the vertical feature, and the anisotropic plasma preferentially treats surfaces of the first and second sidewalls near the opening of the vertical feature as compared to surfaces of the first and second sidewalls near the bottom surface of the vertical feature to form the inhibition gradient on surfaces of the vertical feature.

3. The method of claim 2, wherein the plurality of lateral features extend from openings in the first sidewall or second sidewall of the vertical feature and each comprise a third sidewall and a fourth sidewall on opposite sides of the openings and end surfaces, and the anisotropic plasma preferentially treats surfaces of the third and fourth sidewalls near openings of the plurality of lateral features as compared to surfaces of the third and fourth sidewalls near end surfaces of the vertical feature to form the inhibition gradient on surfaces of the plurality of lateral features.

4. The method of claim 1, wherein depositing the gapfill structure comprises sequentially exposing surfaces of the substrate and the feature therein to a precursor and a reactant.

5. The method of claim 1, wherein the inhibiting gas mixture comprises N₂, NH₃, hydrazine (N₂H₄), N₂+H₂, or combinations thereof.

6. The method of claim 1, wherein the inhibiting gas mixture comprises CO₂ or a hydrocarbon compound having a general formula CₓH_{y} where x has a range of between 1 and 20, and y has a range of between 1 and 20.

7. The method of claim 1, wherein the inhibition gradient comprises a greater intensity of inhibition on surfaces near the opening of the vertical feature and a lower intensity of inhibition on surfaces near a bottom surface of the vertical feature.

8. The method of claim 1, wherein the inhibition gradient comprises a greater intensity of inhibition on surfaces near openings of the lateral trenches and a lower intensity of inhibition on surfaces near bottom surfaces of the lateral trenches.

9. The method of claim 1, wherein the vertical feature comprises a critical dimension between about 45 nm and about 100 nm.

10. The method of claim 1, wherein the vertical feature comprises an aspect ratio between about 80:1 and about 120:1.

11. The method of claim 1, wherein the lateral features comprise a critical dimension between about 10 nm and about 25 nm.

12. The method of claim 1, wherein the lateral features comprise an aspect ratio between about 30:1 and about 50:1.

13. The method of claim 1, wherein depositing the gapfill structure comprises sequentially exposing the substrate and the feature therein to a silicon-containing gas comprising silicon precursors to chemisorb a layer of silicon precursors on the vertical feature and the lateral features, and performing a plasma oxidation process to form a layer of silicon oxide from the silicon precursors chemisorbed on the vertical feature and the lateral features.

14. The method of claim 1, wherein the anisotropic plasma is generated by applying a dual frequency RF power to the inhibiting gas mixture, the dual frequency RF power comprising a high frequency RF power in a range between about 100 W and about 2000 W, and a low frequency RF power in a range between about 25 W and about 250 W.

15. A method of processing a substrate, comprising:
flowing an inhibiting gas mixture into a processing volume of a process chamber having a substrate with a feature formed therein, the feature comprising a vertical feature, and a plurality of lateral features extending from the vertical feature, wherein:
the vertical feature is formed in a top surface of the substrate;
the vertical feature is in fluid communication with the plurality of lateral features extending beneath the top surface of the substrate; and
a longitudinal axis of each the plurality of lateral features extends perpendicular with a longitudinal axis of the vertical feature;
exposing surfaces of the vertical feature and the plurality of lateral features to an anisotropic plasma generated from the inhibiting gas mixture to form an inhibition gradient on surfaces of the vertical feature and the plurality of lateral features;
exposing surfaces of the vertical feature and the plurality of lateral features to a precursor gas to chemisorb a layer of precursors on uninhibited surfaces of the vertical feature and the plurality of lateral features;
exposing the layer of precursors to a reactant plasma of a reactant gas to deposit a gapfill material layer on the vertical feature and the plurality of lateral features; and
cyclically repeating exposure to the precursor gas and deposition of the gapfill material layer to form a gapfill structure and fill the vertical feature and the plurality of lateral feature.

16. The method of claim 15, further comprising purging the inhibiting gas mixture prior to exposing the substrate to the precursor gas, purging the precursor gas prior to exposing the substrate to the reactant of the reactant gas, and purging the reactant gas after exposure to the reactant plasma.

17. The method of claim 15, wherein the inhibition gradient causes growth rate of the gapfill structure on surfaces near an opening of the vertical feature to be less than growth rate of the gapfill structure on surfaces near a bottom surface of the vertical feature, and growth rate of the gapfill structure on surfaces near openings of the lateral features to be less than growth rate of the gapfill structure on surfaces end surfaces of the lateral features.

18. The method of claim 15, wherein the vertical feature comprises a critical dimension between about 45 nm and about 100 nm, and an aspect ratio between about 80:1 and about 120:1.

19. The method of claim 14, wherein the lateral features comprise a critical dimension between about 10 nm and about 25 nm, and an aspect ratio between about 30:1 and about 50:1.

20. A method of processing a substrate, comprising:
positioning a substrate into a processing volume of a process chamber, the substrate having a feature formed therein, the feature comprising a vertical feature, and a plurality of lateral features extending from the vertical feature, wherein:
the vertical feature is formed in a top surface of the substrate;
the vertical feature is in fluid communication with the plurality of lateral features extending beneath the top surface of the substrate; and
a longitudinal axis of each the plurality of lateral features extends substantially parallel with the top surface of the substrate
performing a plasma nitridation process to treat the substrate, the plasma nitridation process preferentially forming amine groups on active sites of surfaces near an opening of the vertical feature and openings of the lateral features as compared to surfaces near a bottom surface of the vertical feature and surfaces near end surfaces of the lateral features, respectively;
exposing surfaces of the vertical feature and the plurality of lateral features to a precursor gas comprising precursors to chemisorb precursors on available active sites remaining on surfaces of vertical feature and the plurality of lateral features;
exposing the precursors on the vertical feature and the plurality of lateral features to a reactant to deposit a gapfill material layer in the vertical feature and lateral features; and
cyclically repeating exposure to the precursor gas and deposition of the gapfill material layer to fill the vertical feature and the plurality of lateral feature.
